(19) United States
(12) Patent Application Publication
(10) Pub. No.: US 2007/0240634 A1
(43) Pub. Date: Oct. 18, 2007

(54) Crystal growing apparatus having a crucible for enhancing the transfer of thermal energy

(76) Inventors: Olexy V. Radkevich, Schaumburg, IL (US); Steven Lewis Wille, Palatine, IL (US); Robert S. Zwolinski, Elmhurst, IL (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/405,835

(22) Filed: Apr. 18, 2006

(51) Int. Cl. C30B 11/00; C30B 15/26

(52) U.S. Cl. 117/204; 117/200; 117/201

(57) ABSTRACT

An apparatus for growing crystals includes a sealed chamber having a crucible and a seed holder disposed therein. The seed holder is selectively positionable within the chamber from a first position relative to the crucible to at least one subsequent position within the crucible. A heater is configured and dimensioned to heat a melt disposed within the crucible and an insulator is included for insulating the heater and the crucible. An actuator rotates at least one of the crucible and the seed holder relative to the other and a support ring suspends the crucible within the sealed chamber. A ceramic thermal shield is disposed atop the support ring and regulates the heat loss from the crucible to an upper portion of the chamber. The crucible has a non-smooth outer surface morphology or a chemically altered outer surface for increasing the absorption or transfer of thermal energy generated by the heater.

### BACKGROUND

The present invention relates to an apparatus for growing single crystals by pulling the single crystals from a melt on a seed. Particularly, the present invention relates to a crystal growing apparatus which significantly improves the transfer of thermal energy from an energy source into a crucible with molten material for growing crystals, and more particularly, the present invention relates to a crucible capable of enhancing the transfer of thermal energy for growing a single crystal from melt.

### Technical Field

Various types of crystals, e.g., sodium chloride, potassium chloride, potassium bromide, lithium fluoride, sodium iodide, cesium iodide, germanium, silicon, lead tellurides, etc., used for optics and semi-conductors are typically grown from a melt or raw material which forms on a seed under controlled chemical conditions.

The Czochralski technique for growing crystals is one technique which originates from the pioneering work of Jan Czochralski in 1917 who first managed to successfully pull single crystals of various metals. Since then the Czochralski technique has been used to grow germanium and silicon and has been extended to grow a wide range of compound semiconductors, oxides, metals, and halides. It is considered the dominant technique for the commercial production of most of these materials. Generally, the process involves the vertical pulling of a seed crystal when contacted with the surface of a molten reservoir of the raw material which is then gradually pulled upwardly with rotation to form the single crystal.

More particularly, the Czochralski technique typically involves the following steps:
filling a suitable crucible with the raw material, e.g., Silicone (Si);
dissolving the raw material in the crucible and keeping its temperature close to the melting point.
inserting a seed crystal while rotating the crucible and adjusting the temperature to start withdrawing the seed crystal (during the first or initial pull, the diameter of the growing crystal will decrease to a few millimeters which is known as the “dash process” which ensures that the crystal will be dislocation free even though the seed crystal may contain some dislocations);
adjusting the growth rate to grow the commercial part of the crystal at a few mm/second at a desired diameter;
Adjusting the temperature, pull rate and rotational speed to maintain the homogeneity of the crystal until the melt is almost exhausted; and
Increasing the pull rate to reduce the diameter of the crystal and establish an “end cone” which signifies the end of homogeneous crystal growth.

It is known that obtaining single crystals with pre-selected properties and perfect crystalline structure is dependent on a host of complicated parameters such as providing stability and axial symmetry of the temperature field in the growing single crystal and the melt surrounding it; maintaining the present solid-liquid interface shape; providing adequate agitation of the melt to wash over the solid-liquid interface; and providing a stable growth rate at the predetermined diameter of the growing single crystal.

Other issues may also arise during crystal growth of a particular material. For example, some compounds may require a very high pressure which must be maintained around the growing crystal area to control the vaporization of a volatile component such as arsenic or phosphorus. In other crystal growing processes, it may be necessary to supply a moderate to high vacuum. Typically, the working zone within the crystal growing apparatus includes some sort of relief valve or is evacuatable to permit control of the zone atmosphere, whether it is pressurized or evacuated during crystal growth.

One particular known apparatus for pulling single crystals from melt on a seed by the Czochralski method includes a sealed chamber with water-cooled walls and a crucible disposed therein such that the vertical axis of the crucible is aligned with the vertical axis of the chamber. The crucible is enclosed within a heater, such as a resistive heater, encompassed by a thermal insulator. The heater is used to provide thermal energy into the crucible. The upper portion of the chamber accommodates a vertical rod having an axis which is aligned with that of the crucible axis. The rod is sealingly received through the top or lid of the chamber and is axially reciprocable. The lower end of the rod carries the seed holder, while its upper end is associated with a rotator which rotates and axially reciprocates the rod.

The initial material is melted in the crucible and the rotating rod with the seed is lowered into the crucible until the seed comes into contact with the melt. The melt temperature is somewhat lowered to discontinue the melting of the seed and thereafter the rod with the seed is slowly pulled while rotated to grow a single crystal on the seed. The diameter is predetermined by correspondingly adjusting the melt temperature and/or the pull rate.

Although the above described known apparatus enables the growth of single crystals of high quality, the transfer of thermal energy from the heater to the crucible is inefficient. This is due to several reasons. First, prior art crucibles are typically machined into shapes that are advantageous for melting, holding and discharging crystalline materials. However, the outer surface finish of the crucible is typically smooth and relatively shiny which reflects a significant amount of the thermal energy generated by the heater.

Second, the surface area of the outer surface finish exposed to the thermal energy of the heater is small as compared to the overall volume of the crucible plus the molten material. This causes less of the thermal energy generated by the heater to be transferred to the molten material within the crucible via the surface area of the outer surface finish.

Third, the smooth outer surface minimizes the absorption or transfer of the thermal energy to the material within the crucible. This is due to the reflectivity of the surface finish and the non-energy absorbing properties of platinum and other inert metals used for the crucible.

Thus, there exists a need to provide a crystal growing apparatus having a crucible which enhances the transfer of thermal energy generated by a heater of the crystal growing apparatus to material within the crucible.

### SUMMARY

The present disclosure relates generally to a crystal growing apparatus for growing crystals and includes a sealed chamber having a crucible and a seed holder disposed therein. The seed holder is selectively positionable within the chamber from a first position relative to the crucible to at least one subsequent position within the crucible. The crucible is adapted to contain a melt therein and enhance the transfer of thermal energy thereto by having a non-smooth outer surface or a chemically altered outer surface. A heater is included which is configured and dimensioned to generate the thermal energy to heat the melt disposed within the crucible and an insulator insolates the heater and the crucible. An actuator is provided which rotates the crucible or the seed holder relative to one another. A support ring is included which suspends the crucible within the sealed chamber and a thermal shield made from a ceramic material with a low coefficient of thermal expansion is disposed atop the support ring for regulating the heat loss from the crucible to an upper portion of the chamber.

Preferably, the crucible is disposed in a lower portion of the chamber and the thermal shield limits heat loss from the lower portion of the chamber to an upper portion of the chamber. In one embodiment of the present invention, the crucible includes a non-smooth surface morphology for the outer surface or a roughened outer surface. Preferably, the surface morphology of the outer surface has a surface roughness which correlates with the wavelength of light or radiation that is generated by the heater for optimally transferring the light or radiation to the material or melt within the crucible, i.e., maximum throughput of light/radiation from the heater to the material or melt. The interaction that is controlled by the surface morphology of the outer surface is the reflection and diffraction that occurs as the thermal energy/radiation impinges on the roughened outer surface. Additionally, the increased surface area facilitates the absorption of the impinging radiation.

The outer surface of the crucible is preferably roughened by mechanical means, such as by shot blasting the smooth outer surface with metallic objects, such as metallic pellets. However, other methods of roughing the outer surface are contemplated within the context of the present disclosure, such as by electrical/thermal means whereby the outer surface of the crucible is electrically or thermally heated to melt the outer surface and create the non-smooth outer surface morphology.

In another embodiment of the present invention, the crucible includes a chemically altered outer surface which increases the absorption or transfer of thermal energy to the material within the crucible. An exemplary chemically altered outer surface includes an oxide of nickel created by electrolytically plating nickel onto an outer surface finish of the crucible followed by providing the electrolytically nickel-plated crucible in an oxidizing environment to create the oxide of nickel or other nickel/metal compounds.

The outer surface finish of the crucible is typically a platinum finish. The chemically altered outer surface preferably has a color other than platinum which in combination with the chemical properties of the metal used in the plating process enhances the absorption or transfer of thermal energy.

### BRIEF DESCRIPTION OF THE DRAWINGS

Several exemplary embodiments of the present invention will now be described in detail with reference to the accompanying drawings:

FIG. 1 is a schematic, cross sectional view of an apparatus for growing crystals having a crucible in accordance with a first embodiment of the present disclosure; and

FIG. 2 is an enlarged schematic cross sectional view of the crucible shown in FIG. 1 illustrating a non-smooth or roughened outer surface in accordance with the present disclosure.

In the drawings, the same or similar elements are denoted by the same reference numerals even though they are depicted in different drawings.

### DETAILED DESCRIPTION OF EXEMPLARY EMBODIMENTS

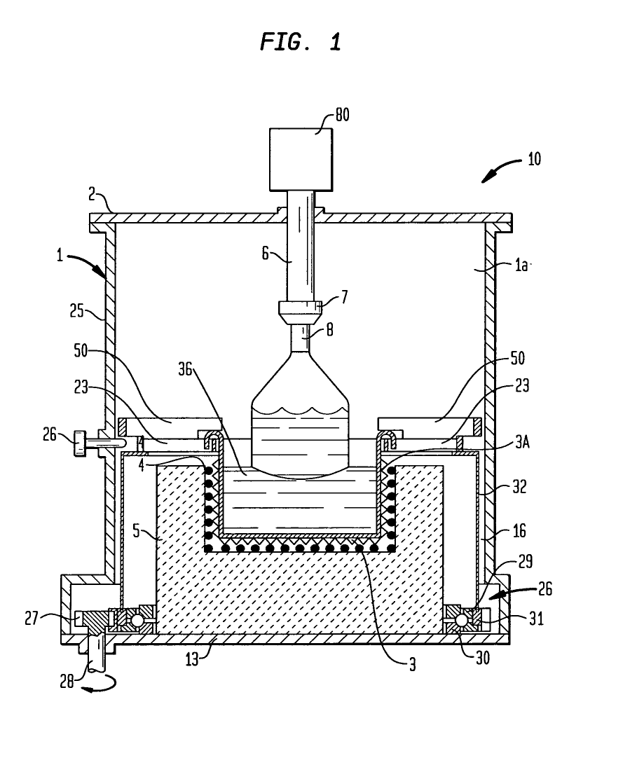

Turning initially to FIG. 1 therein is shown one exemplary embodiment of the presently disclosed crystal growing apparatus 10 for pulling a single crystal from a melt. For the purposes herein, it is envisioned that any known melt may be used from which a single crystal may be pulled, e.g., semi-conductive silicon, alkali halide (e.g., sodium chloride) or a solid solution of tin and lead tellurides. Apparatus 10 is schematically shown and in general includes a sealed chamber 1 with a lid 2. The sealed chamber 1 accommodates a crucible 3 therein which is operatively connected with a drive mechanism 28 for effecting rotation thereof. The crucible contains a melt 36 of the raw crystal material. A heater 4 is included which has an insulator 5 which substantially encloses the crucible 3 and which keeps the temperature of the melt 36 within the crucible 3 at or close to the melting point of the particular melt 36.

An upper portion 1a of the chamber 1 accommodates a rod 6 having an axis which is aligned with that of the axis of the crucible 3. The rod 6 is sealingly received through the lid 2 of the chamber 1 and is axially reciprocable and selectively rotatable. The lower end of the rod 6 carries the holder 7 of a seed 8, while its upper end is associated with an actuator 80 which rotates and axially reciprocates rod 6.

It is envisioned that the insulator 5 may be made from any known suitable insulating material, such as various ceramics. The crucible 3 may comprise quartz, boron nitride, platinum, silicon nitride, etc.

The operative connection between the crucible 3 and its rotation includes a support ring 23 which suspends the crucible 3 therefrom. Rotation of the support ring 23, in turn, rotates the crucible 3. Rotation of the crucible 3 relative to the seed 8 and seed holder 7 is known to promote homogeneity in the growth of the crystal. Joint rotation of the seed 8 and the seed holder 7 also agitates the melt 36 and tends to produce more homogeneous crystal growth. Further, rotating the crucible 3 at any speed in the direction opposite to that of the rotation of the growing single crystal, enables one to effectively control the shape of the solid-liquid interface process and the degree of the agitation of the melt 36.

The crucible 3 is supported by the support ring 23 with aid of hooks 24 provided at the top of the crucible 3. At the horizontal level of the support ring 23, extending sealingly into the chamber 1 through its side wall 25 is a pusher 26 provided for adjusting the position of the crucible 3 in the chamber 1.

The operative connection between the crucible 3 and the drive for the crucible's 3 rotation includes (in addition to the support ring 23 accommodated in the chamber 1) a bearing 26 and a reducing gear of which a driving pinion 27 is mechanically engaged with an output shaft 28 of the rotation drive (not shown) arranged outside the chamber 1. The shaft 28 sealingly extends into the bottom 13 of chamber 1. The bearing 26 includes a rotatable race 29 and a stationary race 30 secured at the bottom 13 of the chamber 1 coaxially with the rod 6 of the holder 7 of the seed 8. The drive member of the reducing gear is in the form of a toothed rim 31 fastened about the rotatable race 29 of the bearing 26 and connected with the support ring 23 for rotating the latter jointly with the crucible 3.

As shown in FIG. 1, a cylindrical stand 32 carries the support ring 23 and has its bottom end secured to the toothed rim 31 coaxially therewith, so that the stand 32 encompasses the heater 4 and the thermal insulator 5. The support ring 23 is carried by the stand 32 with adjustment-wise displacement in a horizontal plane relative to the axis of the rod 6 of the holder 7 of the seed 8.

The ceramic thermal shield 50 is designed and configured to be laid on top of the support ring 23. Preferably, the thermal shield 50 is made from a ceramic material having a low coefficient of thermal expansion and high stability at extreme temperatures such as the various ceramics manufactured by Zicar® Ceramics of Florida, N.Y.

The ceramic thermal shield 50 successfully inhibits NaI or snow accumulation in the molt of feed liquid which surrounds the crucible which is known to quickly upset the heat distribution within the growth zone. Snow accumulation can also block the passage of NaI feeding powder and liquid. In the past snow blockages have been remedied by increasing side heater power to melt the snow (NaI). This, however, creates the undesirable condition of overly hot feed liquid being introduced into the pulling melt. The ceramic thermal shield 50 inhibits NaI build-up by capturing the heat within the well such that snow accumulation is retarded to an acceptable level. The incorporation of the ceramic thermal shield 50 also increases the thermal gradient in the axial direction by virtue of its insulating effect which is also known to promote stable crystal growth. Yet another feature of the ceramic thermal shield 50 is its ability to prevent loss of heater power to the upper regions of the furnace, that is, the upper chamber 1a.

In use, the crucible 3 is mounted on the support ring 23, and the initial raw material is charged into the crucible 3. A sensor can be included which can measure the level of the melt 36 and/or the temperature of the melt 36 as described in U.S. patent application Ser. No. 10/949,236 filed on Sep. 24, 2004 the entire contents of which are incorporated herein by reference. A feeder tube introduces material thallium NaI powder (or the like) into a peripheral annul surrounding the crucible 3. Then the rotation drive of the crucible 3 is energized to transmit the driving torque from the output shaft 28 to the crucible 3 via the driving pinion 27, the toothed rim 31, the cylindrical stand 32 and the support ring 23.

The set screw or pusher 26 is utilized to center the crucible 3 jointly with the support ring 23 such that the axis of the crucible 3 is aligned with the axis of the support ring's 23 rotation and aligned with the axis of the rod 6 of the seed holder 7 (See FIG. 1). The seed 8 is then secured in the holder 7 and the actuator 80 is energized to lower the rod 6. The heater 4 (and any side heaters) is energized to melt the initial material disposed in the crucible 3. The seed 8 is slowly lowered until it comes into contact with the initial material when melted, i.e., the melt 36.

Following the partial melting-over of the seed 8 and establishment of a balanced state between the seed 8 and the melt 36, i.e. the state where neither melting of the seed 8 nor crystallization of the melt thereon takes place, the actuator 80 is again energized to raise and rotate the rod 6 with the seed holder 7. As can be appreciated, controlling the pulling rate of the actuator 80 is indirectly proportional to the diameter of the single crystal, i.e., the lower (or slower) the pull rate the larger the crystal.

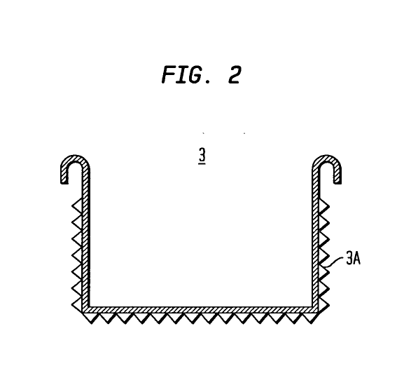

According to an embodiment of the present invention, the crucible 3 includes a non-smooth surface morphology for an outer surface 3A or a roughened outer surface 3A (see FIG. 2). The outer surface 3A can include a platinum finish or other metallic finish. The non-smooth surface morphology preferably includes a pitch from about 1 micron to about 2000 micron. Preferably, the non-smooth surface morphology of the outer surface 3A has a pitch which correlates with the wavelength of light or radiation that is generated by the heater 4 for optimally transferring the light or radiation to the material or melt 36 within the crucible 3, i.e., maximum throughput of light/radiation from the heater 4 to the material or melt 36. That is, the pitch is selected based upon the interaction of the pitch and wavelength of light generated by the heater 4. As an example, if the heater 4 emits infrared radiation having a given infrared wavelength, the pitch of the non-smooth surface morphology is chosen to enable optimum transmission of the infrared wavelength through the outer surface 3A. In other words, the pitch is chosen to optimally minimize the reflection of thermal energy away from the crucible 3. The pitch facilitates the absorption by the crucible 3 of the thermal energy/radiation generated by the heater 4.

The non-smooth surface morphology of the outer surface 3A provides a much greater surface area than a smooth surface morphology, thereby enabling more efficient absorption of energy from the heater 4 by the crucible 3. That is, the greater the surface area, the more surface area for the thermal energy to impinge upon, and a lesser amount of low angle reflectivity of the thermal energy by the outer surface which is typically common with smooth outer surfaces.

The outer surface 3A of the crucible 3 is preferably roughened by mechanical means, such as by shot blasting the smooth outer surface with metallic objects, such as metallic pellets. However, other methods of roughing the outer surface 3A are contemplated within the context of the present disclosure, such as by electrical/thermal means whereby the outer surface of the crucible 3 is electrically or thermally heated to melt the outer surface and create the non-smooth outer surface morphology.

It is also envisioned within the principles of the present embodiments that a non-smooth metallic overlay can be overlaid over the smooth outer surface of a crucible for creating the non-smooth outer surface morphology.

Alternatively, according to an embodiment of the present invention, the outer surface 3A of the crucible 3 is chemically altered which increases the absorption or transfer of thermal energy to the material or melt 36 within the crucible 3. An exemplary chemically altered outer surface includes an oxide of nickel (or other metal, such as, for example, chromium, thallium, tungsten and silver) created by electrolytically plating nickel (or other metal) onto an outer surface finish of the crucible 3 followed by providing the electrolytically nickel-plated crucible in an oxidizing environment to create the oxide of nickel or other nickel/metal compounds. As stated above, the outer surface finish of the crucible 3 is typically a platinum finish.

The chemically altered outer surface, which may include at least one of a sulfide, nitride and an oxide of a metal, preferably has a color other than platinum which in combination with the chemical properties of the metal used in the plating process enhances the absorption or transfer of thermal energy. The chemically altered surface has a surface finish that is stable under the conditions experienced by the crucible 3.

From the foregoing and with reference to the various figure drawings, those skilled in the art will appreciate that certain modifications can also be made to the present invention without departing from the scope of the same. While several embodiments of the invention have been shown in the drawings, it is not intended that the invention be limited thereto, as it is intended that the invention be as broad in scope as the art will allow and that the specification be read likewise. Therefore, the above description should not be construed as limiting, but merely as exemplifications of embodiments. Those skilled in the art will envision other modifications within the scope and spirit of the claims appended hereto.

What is claimed is:

1. An apparatus for growing crystals, comprising:
a sealed chamber having a crucible and a seed holder disposed therein, said seed holder being selectively positionable within said chamber from a first position relative to said crucible to at least one subsequent position within said crucible, said crucible having a non-smooth outer surface morphology and adapted to contain a melt therein;
a heater sufficiently configured and dimensioned to heat said melt disposed within said crucible; and
an actuator for rotating at least one of said crucible and said seed holder relative to the other.

2. An apparatus for growing crystals according to claim 1, further comprising:
an insulator for insulating said heater and said crucible;
a support ring for suspending said crucible within said sealed chamber; and
a thermal shield disposed atop said support ring for regulating the heat loss from the crucible to an upper portion of said chamber, said thermal shield being made from a ceramic material having a low coefficient of thermal expansion.

3. An apparatus for growing crystals according to claim 1, wherein said support ring is mounted for rotation within said chamber such that rotation of said support ring rotates said crucible relative to said seed holder.

4. An apparatus for growing crystals according to claim 1, wherein said crucible is disposed in a lower portion of said chamber and said thermal shield limits heat loss from said lower portion of said chamber to an upper portion of said chamber.

5. An apparatus for growing crystals according to claim 1, wherein said non-smooth outer surface morphology has a pitch of about 1 micron to about 2000 micron.

6. An apparatus for growing crystals according to claim 5, wherein said pitch is selected based upon at least the wavelength of light generated by the heater.

7. An apparatus for growing crystals, comprising:
a sealed chamber having a crucible and a seed holder disposed therein, said seed holder being selectively positionable within said chamber from a first position relative to said crucible to at least one subsequent position within said crucible, said crucible having an outer surface including at least one of a sulfide, nitride and an oxide of a metal, said crucible adapted to contain a melt therein;
a heater sufficiently configured and dimensioned to heat said melt disposed within said crucible; and
an actuator for rotating at least one of said crucible and said seed holder relative to the other.

8. An apparatus for growing crystals according to claim 7, further comprising:
an insulator for insulating said heater and said crucible;
a support ring for suspending said crucible within said sealed chamber; and
a thermal shield disposed atop said support ring for regulating the heat loss from the crucible to an upper portion of said chamber, said thermal shield being made from a ceramic material having a low coefficient of thermal expansion.

9. An apparatus for growing crystals according to claim 7, wherein said support ring is mounted for rotation within said chamber such that rotation of said support ring rotates said crucible relative to said seed holder.

10. An apparatus for growing crystals according to claim 7, wherein said crucible is disposed in a lower portion of said chamber and said thermal shield limits heat loss from said lower portion of said chamber to an upper portion of said chamber.

11. An apparatus for growing crystals according to claim 7, wherein said oxide is created by electrolytically plating nickel onto a platinum finish of the crucible followed by providing said electrolytically nickel-plated crucible in an oxidizing environment to create said oxide.

12. A crucible adapted to contain a melt therein for use in growing crystals using an apparatus for growing crystals, said crucible comprising a non-smooth outer surface morphology.

13. A crucible according to claim 12, wherein said non-smooth outer surface morphology has a pitch of about 1 micron to about 2000 micron.

14. A crucible according to claim 13, wherein said pitch is selected based upon at least the wavelength of light generated by a heater of said apparatus for growing crystals.

15. A crucible according to claim 12, wherein the apparatus for growing crystals comprises:
a sealed chamber having said crucible and a seed holder disposed therein, said seed holder being selectively positionable within said chamber from a first position relative to said crucible to at least one subsequent position within said crucible;
a heater sufficiently configured and dimensioned to heat said melt disposed within said crucible;
an actuator for rotating at least one of said crucible and said seed holder relative to the other;
an insulator for insulating said heater and said crucible;
a support ring for suspending said crucible within said sealed chamber; and
a thermal shield disposed atop said support ring for regulating the heat loss from the crucible to an upper portion of said chamber, said thermal shield being made from a ceramic material having a low coefficient of thermal expansion.

16. A crucible according to claim 15, wherein said support ring is mounted for rotation within said chamber such that rotation of said support ring rotates said crucible relative to said seed holder.

17. A crucible adapted to contain a melt therein for use in growing crystals using an apparatus for growing crystals, said crucible comprising an outer surface including at least one of a sulfide, nitride and an oxide of a metal.

18. A crucible according to claim 17, wherein said oxide is created by electrolytically plating nickel onto a platinum finish of the crucible followed by providing said electrolytically nickel-plated crucible in an oxidizing environment to create said oxide.

19. A crucible according to claim 17, wherein the apparatus for growing crystals comprises:
a sealed chamber having said crucible and a seed holder disposed therein, said seed holder being selectively positionable within said chamber from a first position relative to said crucible to at least one subsequent position within said crucible;
a heater sufficiently configured and dimensioned to heat said melt disposed within said crucible;
an actuator for rotating at least one of said crucible and said seed holder relative to the other;
an insulator for insulating said heater and said crucible;
a support ring for suspending said crucible within said sealed chamber; and
a thermal shield disposed atop said support ring for regulating the heat loss from the crucible to an upper portion of said chamber, said thermal shield being made from a ceramic material having a low coefficient of thermal expansion.

20. A crucible according to claim 19, wherein said support ring is mounted for rotation within said chamber such that rotation of said support ring rotates said crucible relative to said seed holder.
